(19) United States
(12) Patent Application Publication
(10) Pub. No.: US 2024/0071730 A1
(43) Pub. Date: Feb. 29, 2024

(54) PLASMA PROCESSING APPARATUS

(71) Applicant: Tokyo Electron Limited, Tokyo (JP)

(72) Inventor: Masaki HIRAYAMA, Fuchu City (JP)

(21) Appl. No.: 18/453,350

(22) Filed: Aug. 22, 2023

(30) Foreign Application Priority Data
Aug. 25, 2022 (JP) 2022-134044

(51) Int. Cl. H01J 37/32

(52) U.S. Cl. CPC H01J 37/32623; H01J 37/3244; H01J 37/32568; H01J 2237/0266

(57) ABSTRACT

A plasma processing apparatus includes a chamber having a sidewall and providing a processing space; a substrate support provided in the processing space; a first electrode provided above the processing space; a second electrode provided above the processing space and below the first electrode, wherein the second electrode is configured to provide a plasma generation space between the first electrode and the second electrode and provides a plurality of through holes that guide active species into the processing space; an inlet portion configured to introduce electromagnetic waves into the plasma generation space; and a choke configured to suppress emission of electromagnetic waves to the processing space via the plurality of through holes. The choke includes a dielectric member in contact with a bottom surface of a peripheral edge portion of the second electrode. The dielectric member protrudes inside the chamber.

### CROSS-REFERENCE TO RELATED APPLICATION

This application is based upon and claims the benefit of priority from Japanese Patent Application No. 2022-134044, filed on Aug. 25, 2022, the entire contents of which are incorporated herein by reference.

### TECHNICAL FIELD

An exemplary embodiment of the present disclosure relates to a plasma processing apparatus.

### BACKGROUND

A plasma processing apparatus is used in plasma processing of substrates. The plasma processing apparatus may include a chamber, a substrate support, an upper electrode, and an electromagnetic radiation port. The chamber provides a processing space. The substrate support is provided within the processing space. The upper electrode is provided above the substrate support and configured to eject gas into the processing space. The electromagnetic radiation port is configured to introduce electromagnetic waves into the processing space from a space around the upper electrode. Patent Document 1 below discloses such a plasma processing apparatus.

### PRIOR ART DOCUMENTS

### Patent Documents

Patent Document 1: Japanese Patent Laid-Open Publication No. 2021-96934

### SUMMARY

According to an embodiment of the present disclosure, a plasma processing apparatus includes: a chamber having a sidewall and providing a processing space; a substrate support provided in the processing space; a first electrode provided above the processing space; a second electrode provided above the processing space and below the first electrode, wherein the second electrode is configured to provide a plasma generation space between the first electrode and the second electrode and provides a plurality of through holes that guide active species generated in the plasma generation space into the processing space; an inlet portion configured to introduce electromagnetic waves into the plasma generation space; and a choke configured to suppress emission of electromagnetic waves from the plasma generation space to the processing space via the plurality of through holes, wherein the choke comprises a dielectric member which is in contact with a bottom surface of a peripheral edge portion of the second electrode, and the dielectric member protrudes inside the chamber with respect to the side wall.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a plasma processing apparatus according to an exemplary embodiment.

FIG. 2 is a view illustrating a plasma processing apparatus according to another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the drawings. In each drawing, the same or corresponding components will be denoted by the same reference numerals.

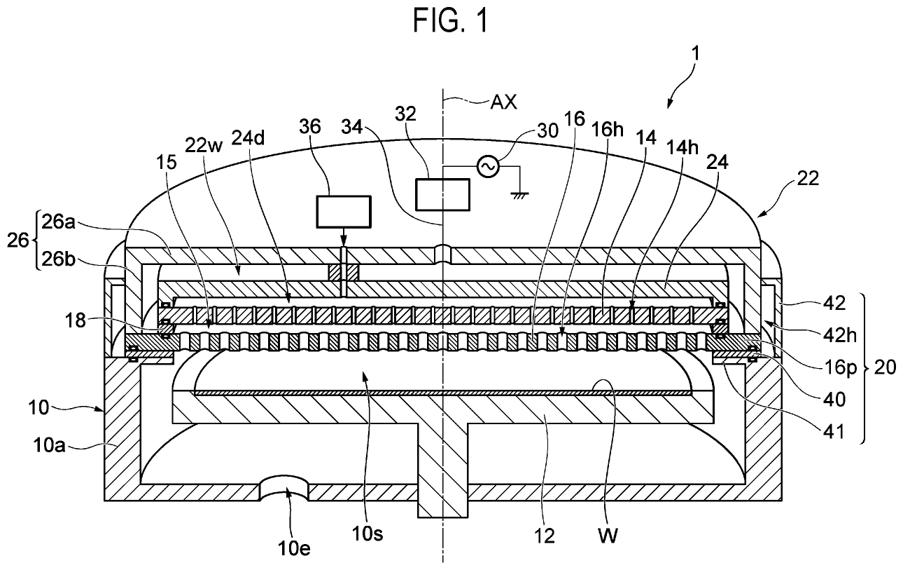

FIG. 1 is a view illustrating a plasma processing apparatus according to an exemplary embodiment. The plasma processing apparatus 1 illustrated in FIG. 1 includes a chamber 10, a substrate support 12, a first electrode 14, a second electrode 16, an inlet portion 18, and a choke 20.

The chamber 10 provides therein a processing space 10s. In the plasma processing apparatus 1, a substrate W is processed in the processing space 10s. The chamber 10 is made of a metal such as aluminum and is grounded. The chamber 10 includes a side wall 10a and is open at an upper end thereof. The chamber 10 and the side wall 10a may have a substantially cylindrical shape. The processing space 10s is provided inside the side wall 10a. The center axis of each of the chamber 10, the side wall 10a, and the processing space 10s is an axis AX. The chamber 10 may have a corrosion-resistant film on the surface thereof. The corrosion-resistant film may be a ceramic membrane including an yttrium oxide film, an yttrium oxide fluoride film, an yttrium fluoride film, an yttrium oxide, an yttrium fluoride, or the like.

The bottom of the chamber 10 provides an exhaust port 10e. An exhaust apparatus is connected to the exhaust port 10e. The exhaust apparatus may include a vacuum pump, such as a dry pump and/or a turbo molecular pump, and an automatic pressure control valve.

The substrate support 12 is provided within the processing space 10s. The substrate support 12 is configured to support a substrate W placed on the top surface thereof substantially horizontally. The substrate support 12 has a substantially disk-like shape. The center axis of the substrate support 12 is the axis AX.

The first electrode 14 is provided above the processing space 10s. The first electrode 14 is made of a conductor such as aluminum and has a substantially disk-like shape. The center axis of the first electrode 14 is the axis AX. The first electrode 14 may provide a plurality of gas holes 14h configured to introduce gas into a plasma generation space 15, which will be described later. The plurality of gas holes 14h extend in the thickness direction (vertical direction) of the first electrode 14 and penetrate the first electrode 14.

The second electrode 16 is provided above the processing space 10s and below the first electrode 14. The second electrode 16 may extend substantially in parallel with the first electrode 14. The second electrode 16 is made of a conductor such as aluminum and has a substantially disk-like shape. The center axis of the second electrode 16 is the axis AX. The second electrode 16 closes the upper end opening of the chamber 10 together with a dielectric member 40 which will be described later. That is, the second electrode 16 defines the processing space 10s from an upper space.

The second electrode 16 provides the plasma generation space 15 between the first electrode 14 and the second electrode 16. In the plasma generation space 15, plasma is generated from gas by electromagnetic waves. The second electrode 16 provides a plurality of through holes 16h configured to guide active species from the plasma within the plasma generation space 15 to the processing space 10s. The plurality of through holes 16h extend in the thickness direction (vertical direction) of the second electrode 16 and penetrate the second electrode 16. The cross-sectional areas of the plurality of through holes 16h are set so as to suppress deactivation of active species when passing through the plurality of through holes 16h, and are relatively large.

The inlet portion 18 is configured to introduce electromagnetic waves into the plasma generation space 15 in order to generate plasma in the plasma generation space 15. The inlet portion 18 is made of a dielectric material such as quartz, aluminum nitride, or aluminum oxide. The inlet portion 18 may be substantially ring-shaped, and the center axis thereof may be the axis AX. The inlet portion 18 may be sandwiched between the peripheral edge portion of the first electrode 14 and a peripheral edge portion 16p of the second electrode 16. The electromagnetic waves introduced into the plasma generation space 15 from the inlet portion 18 may be radio-frequency waves, such as VHF waves or UHF waves. The electromagnetic waves are generated by a radio-frequency power supply, which will be described later. The electromagnetic waves propagate through a waveguide part 22 to the inlet portion 18 and are introduced into the plasma generation space 15 from the inlet portion 18.

The waveguide part 22 provides a waveguide 22w. In an embodiment, the waveguide part 22 may include the first electrode 14, the second electrode 16, an upper electrode 24, and an upper wall 26. The upper electrode 24 is provided above the first electrode 14. The upper electrode 24 is made of a conductor such as aluminum, and has a substantially disk-like shape. The center axis of the upper electrode 24 is the axis AX.

The upper electrode 24 provides a gas diffusion space 24d between the first electrode 14 and the upper electrode 24. A gas supplier 36 is connected to the gas diffusion space 24d. The gas output from the gas supplier 36 is supplied to the plasma generation space 15 via the gas diffusion space 24d and the plurality of gas holes 14h.

The upper wall 26 is made of a conductor such as aluminum. The upper wall 26 is provided to cover the first electrode 14, the second electrode 16, and the upper electrode 24, and forms the waveguide 22w. The upper wall 26 may include an upper portion 26a and a side portion 26b.

The upper portion 26a has a substantially disk-like shape, and the center axis thereof is the axis AX. The upper portion 26a extends above the upper electrode 24 in parallel with the top surface of the upper electrode 24. The side portion 26b has a substantially cylindrical shape, and the center axis thereof is the axis AX. The side portion 26b extends downward from the peripheral edge of the upper portion 26a to surround the first electrode 14, the inlet portion 18, and the upper electrode 24. The lower end of the side portion 26b is in contact with the top surface of the peripheral edge portion 16p of the second electrode 16.

The waveguide 22w extends between the upper portion 26a and the top surface of the upper electrode 24, between the side portion 26b and the outer peripheral surface of the upper electrode 24, between the side portion 26b and the outer peripheral surface of the first electrode 14, and between the side portion 26b and the outer peripheral surface of the inlet portion 18.

The plasma processing apparatus 1 further includes a radio-frequency power supply 30 and a matcher 32. The radio-frequency power supply 30 is configured to generate radio-frequency power. The electromagnetic waves introduced into the chamber 10 are generated based on the radio-frequency power generated by the radio-frequency power supply 30. The radio-frequency power supply 30 may be connected to the upper electrode 24 via the matcher 32 and an electric line 34. The matcher 32 includes a matching circuit configured to match the load impedance of the radio-frequency power supply 30 with the output impedance of the radio-frequency power supply 30. The electric line 34 extends downward from the matcher 32 and is connected to the center of the top surface of the upper electrode 24. The electric line 34 may extend along the axis AX.

The choke 20 is configured to suppress the emission of electromagnetic waves from the plasma generation space 15 to the processing space 10s through the plurality of through holes 16h. The choke 20 includes the dielectric member 40. The choke 20 may further include a peripheral edge portion 16p of the second electrode 16, a first conductor portion 41, and a second conductor portion 42.

The dielectric member 40 is made of a dielectric material such as aluminum oxide, aluminum nitride, yttrium oxide, quartz glass, tetrafluoroethylene, or the like. The dielectric member 40 may be a plate-shaped member or may have a ring shape. The dielectric member 40 may be arranged such that the center axis thereof coincides with axis AX.

The dielectric member 40 is in contact with the bottom surface of the peripheral edge portion 16p of the second electrode 16. The dielectric member 40 protrudes inside the chamber 10 with respect to the side wall 10a. The dielectric member 40 extends to the vicinity of the outermost through holes 16h among the plurality of through holes 16h. The shortest distance between the outermost holes 16h among the plurality of through-holes 16h and the dielectric member 40 is 0 or more and may be 1/10 or less of the wavelength of the surface waves (electromagnetic waves) on the bottom surface of the second electrode 16.

The first conductor portion 41 is formed of a conductor such as aluminum. The first conductor portion 41 extends inside the chamber 10 from the side wall 10a of the chamber 10 and is in contact with the bottom surface of the dielectric member 40. The first conductor portion 41 may be plate-shaped or ring-shaped. The position of the inner end of the first conductor portion 41 in a direction orthogonal to the axis AX may be the same or substantially the same as the position of the inner end of the dielectric member 40 in the same direction. The first conductor portion 41 has the same potential as the chamber 10 and is grounded. The first conductor portion 41 may be provided integrally with the side wall 10a of the chamber 10.

The second conductor portion 42 is provided outside the processing space 10s. The second conductor portion 42 is made of a conductor such as aluminum. The second conductor portion 42 provides a cavity 42h. The cavity 42h continues to the outer end of the dielectric member 40. In the illustrated example, the cavity 42h extends above the bottom surface of dielectric member 40. That is, the vertical position of the lower end of the cavity 42h is the same or substantially the same as the vertical position of the bottom surface of the dielectric member 40. In another example, the cavity 42h may extend below the top surface of the dielectric member 40. That is, the vertical position of the upper end of the cavity 42h may be the same or substantially the same as the vertical position of the top surface of the dielectric member 40.

The cavity 42h may have a ring shape and may extend around the axis AX. In the illustrated example, the cavity 42h is formed between the second conductor portion 42 and the side portion 26b of the upper wall 26, between the second conductor portion 42 and the peripheral edge portion 16p of the second electrode 16, and between the second conductor portion 42 and the dielectric member 40. In this example, the second conductor portion 42 has a cylindrical shape closed at the upper end. In this example, the lower end of the second conductor portion 42 may be in contact with the upper end of the side wall 10a of the chamber 10. The cavity 42h may be filled with air. Alternatively, a gas such as nitrogen gas, argon gas, or nitrogen fluoride gas may be encapsulated in the cavity 42h.

The dielectric member 40 and the cavity 42h are designed such that the choke 20 has high impedance with respect to electromagnetic waves. That is, the dielectric member 40 and the cavity 42h are designed such that parallel resonance of electromagnetic waves occurs in the choke 20. In addition, as described above, the dielectric member 40 extends to the vicinity of the outermost through holes 16h among the plurality of through holes 16h. With the choke 20, electromagnetic waves are immediately returned toward the second electrode 16 even if the electromagnetic waves are emitted from the plurality of through holes 16h. Therefore, the emission of electromagnetic waves from the plasma generation space 15 to the processing space 10s is suppressed.

In addition, in the plasma processing apparatus 1, the first conductor portion 41 warps upward, that is, in the direction in which the dielectric member 40 is positioned with respect to the first conductor portion 41 due to the temperature rise caused by the heat input from the plasma. Therefore, high adhesion between each of the first conductor portion 41 and the peripheral edge portion 16p of the second electrode 16 and the dielectric member 40 is ensured. Therefore, the occurrence of a gap between the dielectric member 40 and each of the first conductor portion 41 and the peripheral edge portion 16p of the second electrode 16 is suppressed.

In addition, the dielectric member 40 and the first conductor portion 41 extend along the peripheral edge portion 16p of the second electrode 16. Therefore, the gas flow in the processing space 10s is suppressed from being disturbed by the dielectric member 40 and the first conductor portion 41. In addition, a sufficient capacitive component can be obtained in the choke 20 to function as a choke.

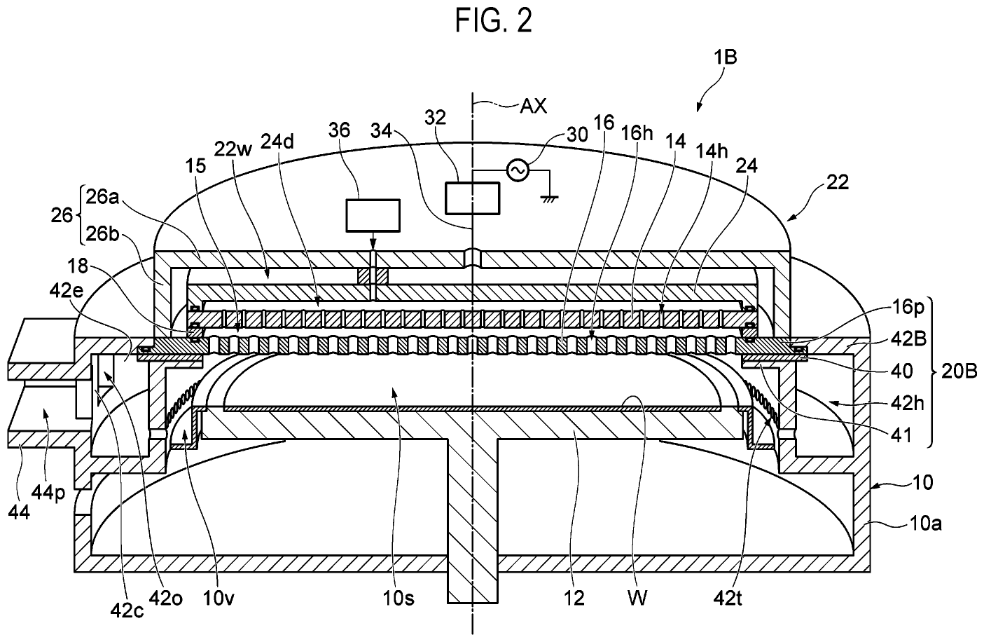

Below, reference will be made to FIG. 2. FIG. 2 is a view illustrating a plasma processing apparatus according to another exemplary embodiment. Below, the plasma processing apparatus 1B illustrated in FIG. 2 will be described from the viewpoint of differences between the plasma processing apparatus 1B and the plasma processing apparatus 1.

The plasma processing apparatus 1B includes a choke 20B instead of the choke 20. The choke 20B differs from the choke 20 in that it includes a second conductor portion 42B instead of the second conductor portion 42.

The second conductor portion 42B is formed of a conductor such as aluminum. The second conductor portion 42B is an exhaust duct that provides a cavity 42h. The second conductor portion 42B may be provided by the side wall 10a of the chamber 10. The second conductor portion 42B may extend in the circumferential direction around the axis AX. That is, the cavity 42h in the second conductor portion 42B may have a ring shape and may extend in the circumferential direction around the axis AX.

As illustrated in FIG. 2, an exhaust path 10v is provided between the second conductor portion 42B and the substrate support 12. In the plasma processing apparatus 1B, the first conductor portion 41 extends above the exhaust path 10v. The second conductor portion 42B provides a plurality of holes 42t that interconnect the exhaust path 10v and the cavity 42h. The plurality of holes 42t may be formed in the inner peripheral wall of the second conductor portion 42B, i.e., the exhaust duct, and may be arranged along the circumferential direction.

In the plasma processing apparatus 1B, the outer end of the dielectric member 40 protrudes into the cavity 42h in the second conductor portion 42B. In addition, in the illustrated example, the cavity 42h in the second conductor portion 42B extends below the top surface of the dielectric member 40. That is, the vertical position of the upper end of the cavity 42h in the second conductor portion 42B is the same or substantially the same as the vertical position of the top surface of the dielectric member 40. In addition, in another example, the cavity 42h in the second conductor portion 42B may extend above the bottom surface of the dielectric member 40. That is, the vertical position of the lower end of the cavity 42h in the second conductor portion 42B may be the same or substantially the same as the vertical position of the bottom surface of the dielectric member 40.

The outer peripheral wall 42e of the second conductor portion 42B, i.e., the exhaust duct, provides an opening 42o. Another exhaust duct 44 is connected to the second conductor portion 42B, that is, the exhaust duct. The exhaust duct 44 provides an exhaust path 44p. The exhaust duct 44 and the exhaust path 44p extend in a direction away from the chamber 10, for example, in a radial direction with respect to the axis AX. The exhaust path 44p is connected to the cavity 42h via the opening 42o. In addition, an exhaust apparatus is connected to the exhaust duct 44. The exhaust apparatus may include a dry pump and/or a vacuum pump such as a turbo molecular pump and an automatic pressure control valve.

A short-circuit portion 42c is provided in the opening 42o. The short-circuit portion 42c is made of a conductor such as aluminum, and has, for example, a rod shape. The short-circuit portion 42c electrically connects a pair of edge portions that define the opening 42o, i.e., the upper edge portion and the lower edge portion, to each other. The short-circuit portion 42c separates the opening 42o into a plurality of portions. The length of each of the plurality of portions of the opening 42o in the circumferential direction may be set to 1/10 or less of the wavelength of the electromagnetic waves in the cavity 42h in the second conductor portion 42B. Due to the short-circuit portion 42c, the outer peripheral wall 42e functions as a short-circuit surface against electromagnetic waves even in the portion where the opening 42o is provided.

In the plasma processing apparatus 1B, the outer end of the dielectric member 40 protrudes into the cavity 42h in the second conductor portion 42B. Therefore, discharge in the second conductor portion 42B, that is, in the cavity 42h of the exhaust duct, is suppressed. In addition, the outer end of the dielectric member 40 extends at the upper end portion (or lower end portion) of the cavity 42h. Therefore, disturbance of the gas flow in the second conductor portion 42B, that is, the cavity 42h in the exhaust duct, is suppressed by the dielectric member 40.

According to an exemplary embodiment, it is possible to suppress the emission of electromagnetic waves into a processing space in a plasma processing apparatus that supplies active species to the processing space from plasma generated by the electromagnetic waves in a plasma generation space.

Although various exemplary embodiments have been described above, the present disclosure is not limited to the above-described exemplary embodiments, and various additions, omissions, substitutions, and changes may be made. In addition, elements in different embodiments may be combined to form other embodiments.

Various exemplary embodiments included in the present disclosure will now be described in [E1] to [E12] below.
[E1] A plasma processing apparatus includes: a chamber having a sidewall and providing a processing space; a substrate support provided in the processing space; a first electrode provided above the processing space; a second electrode provided above the processing space and below the first electrode, wherein the second electrode is configured to provide a plasma generation space between the first electrode and the second electrode and provides a plurality of through holes configured to guide active species generated in the plasma generation space into the processing space; an inlet portion configured to introduce electromagnetic waves into the plasma generation space; and a choke configured to suppress emission of electromagnetic waves from the plasma generation space to the processing space via the plurality of through holes, wherein the choke includes a dielectric member which is in contact with a bottom surface of a peripheral edge portion of the second electrode, and the dielectric member protrudes inside the chamber with respect to the side wall.
[E2] The plasma processing apparatus described in E1, wherein the choke further includes: the peripheral edge portion of the second electrode; a first conductor portion extending inside the chamber from the side wall of the chamber and being in contact with a bottom surface of the dielectric member; and a second conductor portion provided outside the processing space and providing a cavity continuous to an outer end of the dielectric member.
[E3] The plasma processing apparatus described in E2, wherein the second conductor portion is an exhaust duct providing the cavity connected to the processing space.
[E4] The plasma processing apparatus described in E3, wherein the outer end of the dielectric member protrudes into the cavity in the exhaust duct.
[E5] The plasma processing apparatus described in E3 or E4, wherein the substrate support and the exhaust duct provide therebetween an exhaust path connected to the cavity, the exhaust duct provides a plurality of holes that connect the exhaust path and the cavity to each other, and the first conductor portion extends above the exhaust path.
[E6] The plasma processing apparatus described in any one of E2 to E5, wherein the cavity extends below a top surface of the dielectric member.
[E7] The plasma processing apparatus described in any one of E2 to E5, wherein the cavity extends above a bottom surface of the dielectric member.
[E8] The plasma processing apparatus described in any one of E2 to E7, wherein each of the dielectric member and the first conductor portion has a ring shape and extends around a center axis of the chamber.
[E9] The plasma processing apparatus described in E8, wherein the cavity has a ring shape and extends around the center axis of the chamber.
[E10] The plasma processing apparatus described in any one of E1 to E9, wherein the inlet portion is provided between the peripheral edge portion of the second electrode and a peripheral edge portion of the first electrode.
[E11] The plasma processing apparatus described in any one of E1 to E10, wherein the first electrode provides a plurality of gas holes configured to introduce gas into the plasma generation space.
[E12] The plasma processing apparatus described in any one of E1 to E11, wherein the electromagnetic waves are VHF waves or UHF waves.

From the foregoing, it will be appreciated that various embodiments of the present disclosure have been described herein for purposes of illustration, and that various modifications may be made without departing from the scope and spirit of the present disclosure. Therefore, the various embodiments disclosed herein are not intended to be limiting, and the true scope and spirit thereof are indicated by the appended claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a chamber having a side wall and providing a processing space;
a substrate support provided in the processing space;
a first electrode provided above the processing space;
a second electrode provided above the processing space and below the first electrode, wherein the second electrode is configured to provide a plasma generation space between the first electrode and the second electrode and provides a plurality of through holes that guide active species generated in the plasma generation space into the processing space;
an inlet portion configured to introduce electromagnetic waves into the plasma generation space; and
a choke configured to suppress emission of electromagnetic waves from the plasma generation space to the processing space via the plurality of through holes,
wherein the choke comprises a dielectric member which is in contact with a bottom surface of a peripheral edge portion of the second electrode, and
wherein the dielectric member protrudes inside the chamber with respect to the side wall.

2. The plasma processing apparatus of claim 1, wherein the choke further comprises:
the peripheral edge portion of the second electrode;
a first conductor portion extending inside the chamber from the side wall of the chamber and being in contact with a bottom surface of the dielectric member; and
a second conductor portion provided outside the processing space and providing a cavity continuous to an outer end of the dielectric member.

3. The plasma processing apparatus of claim 2, wherein the second conductor portion is an exhaust duct providing the cavity connected to the processing space.

4. The plasma processing apparatus of claim 3, wherein the outer end of the dielectric member protrudes into the cavity in the exhaust duct.

5. The plasma processing apparatus of claim 4, wherein the substrate support and the exhaust duct provide therebetween an exhaust path connected to the cavity,
wherein the exhaust duct provides a plurality of holes that connect the exhaust path and the cavity to each other, and
wherein the first conductor portion extends above the exhaust path.

6. The plasma processing apparatus of claim 3, wherein the substrate support and the exhaust duct provide therebetween an exhaust path connected to the cavity,
wherein the exhaust duct provides a plurality of holes that connect the exhaust path and the cavity to each other, and
wherein the first conductor portion extends above the exhaust path.

7. The plasma processing apparatus of claim 2, wherein the cavity extends below a top surface of the dielectric member.

8. The plasma processing apparatus of claim 2, wherein the cavity extends above the bottom surface of the dielectric member.

9. The plasma processing apparatus of claim 2, wherein each of the dielectric member and the first conductor portion has a ring shape and extends around a center axis of the chamber.

10. The plasma processing apparatus of claim 9, wherein the cavity has a ring shape and extends around the center axis of the chamber.

11. The plasma processing apparatus of claim 1, wherein the inlet portion is provided between the peripheral edge portion of the second electrode and a peripheral edge portion of the first electrode.

12. The plasma processing apparatus of claim 1, wherein the first electrode provides a plurality of gas holes configured to introduce gas into the plasma generation space.

13. The plasma processing apparatus of claim 1, wherein the electromagnetic waves are VHF waves or UHF waves.
